(19) United States
(12) Patent Application Publication
(10) Pub. No.: US 2026/0013217 A1
(43) Pub. Date: Jan. 8, 2026

(54) STRUCTURE WITH HIGH VOLTAGE TRANSISTOR, MIDDLE VOLTAGE TRANSISTOR AND LOW VOLTAGE TRANSISTOR AND FABRICATING METHOD OF THE SAME

(71) Applicant: UNITED MICROELECTRONICS CORP., Hsin-Chu City (TW)

(72) Inventor: Shin-Hung Li, Nantou County (TW)

(73) Assignee: UNITED MICROELECTRONICS CORP., Hsin-Chu City (TW)

(21) Appl. No.: 18/793,933

(22) Filed: Aug. 4, 2024

(30) Foreign Application Priority Data
Jul. 2, 2024 (TW) 113124675

(51) Int. Cl. H01L 27/088; H01L 21/8234; H01L 29/423

(52) U.S. Cl. CPC H10D 84/834; H10D 64/518; H10D 84/0142; H10D 84/0151; H10D 84/0158; H10D 84/038

(57) ABSTRACT

A structure with a high voltage transistor, a middle voltage transistor and a low voltage transistor includes a substrate. The substrate includes a high voltage region, a middle voltage region and a low voltage region. A high voltage transistor is disposed within in the high voltage region. The high voltage transistor includes a first gate dielectric layer embedded in the substrate, and a first gate structure disposed on the first gate dielectric layer. A middle voltage transistor is disposed in the middle voltage region. The middle voltage transistor includes a second gate dielectric layer embedded in the substrate. A second gate structure is disposed on the second gate dielectric layer, wherein a thickness of the second gate structure is greater than a thickness of the first gate structure.

### BACKGROUND OF THE INVENTION

### 1. Field of the Invention

The present invention relates to a structure with a high voltage transistor, a middle voltage transistor and a low voltage transistor and a fabricating method of the same, and more particularly to a fabricating method which maintains uniform performance of the low voltage transistor.

### 2. Description of the Prior Art

Transistor is one of the most important components in integrated circuits. Its function determines the quality of the electrical circuits. It is an important technical indicator in today's semiconductor industry. Taking the MOS transistors as an example, when different bias voltages are applied to the gate, the current between the source and drain can be turned on or off.

MOS transistors are divided into low voltage, middle voltage and high voltage according to the operating range. Low voltage transistors, middle voltage transistors and high voltage transistors can serve as elements to form switches or amplifier circuits.

Because high voltage transistors are applied with high voltages, generally above 500 volts, high voltage transistors need to have a higher breakdown voltage to withstand high input voltages. Compared with high voltage transistors, middle voltage transistors have a lower operating voltage, generally between ten to hundreds of volts, and are mainly used in middle power ranges. The operating voltage of low voltage transistors is generally below 40 volts.

As the size of electronic products shrinks, it is necessary to integrate multiple components on a single chip. It is also expected that by placing more components on a small chip to make the integrated chip function better.

### SUMMARY OF THE INVENTION

In view of this, the present invention provides a fabricating method of a structure with a high voltage transistor, a middle voltage transistor and a low voltage transistor to integrate transistors operating at different voltages onto the same chip.

According to a preferred embodiment of the present invention, a structure with a high voltage transistor, a middle voltage transistor and a low voltage transistor includes a substrate, wherein the substrate includes a high voltage region, a middle voltage region and a low voltage region. A high voltage transistor is disposed in the high voltage region. The high voltage transistor includes a first gate dielectric layer embedded in the substrate and a first gate structure disposed on the first gate dielectric layer. A middle voltage transistor is disposed in the middle voltage region. The middle voltage transistor includes a second gate dielectric layer embedded in the substrate, and a second gate structure disposed on the second gate dielectric layer. A low voltage transistor is disposed in the low voltage region. The low voltage transistor includes a fin structure protruding from a first surface of the substrate, and a third gate structure covering and crossing the fin structure. A shallow trench insulation (STI) covers the first surface of the substrate in the low voltage region and is disposed at one side of the fin structure. The fin structure protrudes from the STI, and a top surface of the STI is aligned with a top surface of the second gate dielectric layer.

According to another preferred embodiment of the present invention, a structure with a high voltage transistor, a middle voltage transistor and a low voltage transistor includes a substrate, wherein the substrate includes a high voltage region, a middle voltage region and a low voltage region. A high voltage transistor is disposed in the high voltage region, wherein the high voltage transistor includes a first gate dielectric layer embedded in the substrate and a first gate structure disposed on the first gate dielectric layer. A middle voltage transistor is disposed in the middle voltage region, wherein the middle voltage transistor includes a second gate dielectric layer embedded in the substrate, and a second gate structure disposed on the second gate dielectric layer, wherein a thickness of the second gate structure is greater than a thickness of the first gate structure.

According to another preferred embodiment of the present invention, a fabricating method of a structure with a high voltage transistor, a middle voltage transistor and a low voltage transistor includes providing a substrate, wherein the substrate includes a high voltage region, a middle voltage region and a low voltage region. The low voltage region of the substrate has a first surface. At least one fin structure protrudes from the first surface, a shallow trench insulation (STI) is disposed at one side of the fin structure, two first deep trench isolations are embedded in the substrate of the high voltage region, and two second deep trench isolations are embedded in the substrate of the middle voltage region. The high voltage region of the substrate has a second surface, and the middle voltage region of the substrate has a third surface, the second surface and the third surface are aligned, and the first surface is lower than the second surface. Next, the first surface and the second surface are etched to form a first trench and a second trench, wherein the first trench is disposed between the two first deep trench isolations and the second trench is disposed between the two second deep trench isolations. After that, a first silicon oxide layer and a second silicon oxide layer are respectively formed to fill the first trench and the second trench, wherein the first silicon oxide layer and the second silicon oxide layer are aligned. Thereafter, part of the second silicon oxide layer is removed to make a top surface of the second silicon oxide layer lower than a top surface of the first silicon oxide layer. Later, part of the STI is removed to expose part of the fin structure. Finally, after removing part of the second silicon oxide layer, a first gate structure, a second gate structure and a third gate structure are formed to respectively cover the first silicon oxide layer, the second silicon oxide layer and the fin structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a fabricating method of a structure with a high voltage transistor, a middle voltage transistor and a low voltage transistor according to a first embodiment of the present invention, wherein:

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4;

FIG. 6 is a fabricating stage in continuous of FIG. 5;

FIG. 7 is a fabricating stage in continuous of FIG. 6; and

FIG. 8 is a fabricating stage in continuous of FIG. 7.

FIG. 9 depict a fabricating method of a structure with a high voltage transistor, a middle voltage transistor and a low voltage transistor according to a second preferred embodiment of the present invention.

FIG. 10 to FIG. 11 depict a fabricating method of a structure with a high voltage transistor, a middle voltage transistor and a low voltage transistor according to a third preferred embodiment of the present invention, wherein:

FIG. 11 depicts a fabricating stage in continuous of FIG. 10.

### DETAILED DESCRIPTION

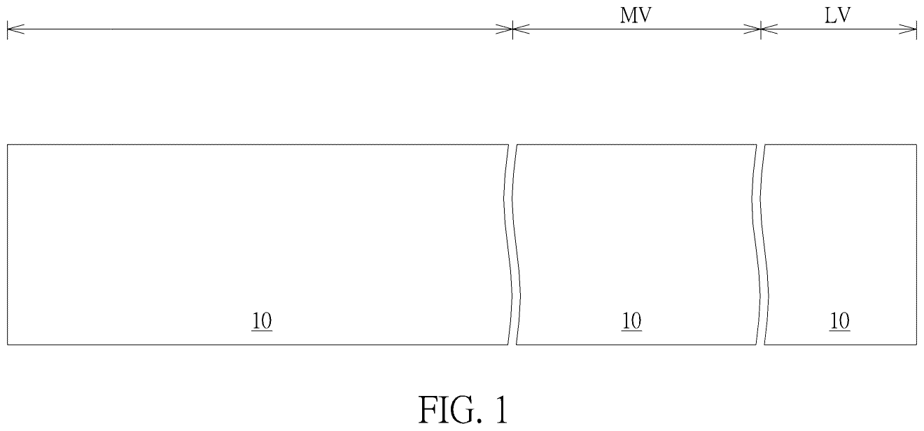

FIG. 1 to FIG. 8 depict a fabricating method of a structure with a high voltage transistor, a middle voltage transistor and a low voltage transistor according to a first embodiment of the present invention.

As shown in FIG. 1, a substrate 10 is provided. The substrate 10 may a silicon substrate, a germanium substrate, a gallium arsenide substrate, a silicon germanium substrate, an indium phosphide substrate, a gallium nitride substrate, a silicon carbide substrate or a silicon on insulator substrate. The substrate 10 includes a high voltage region HV, a middle voltage region MV and a low voltage region LV. At this stage, a top surface of the high voltage region HV, a top surface of the middle voltage region MV and a top surface of the low voltage region LV of the substrate 10 are coplanar.

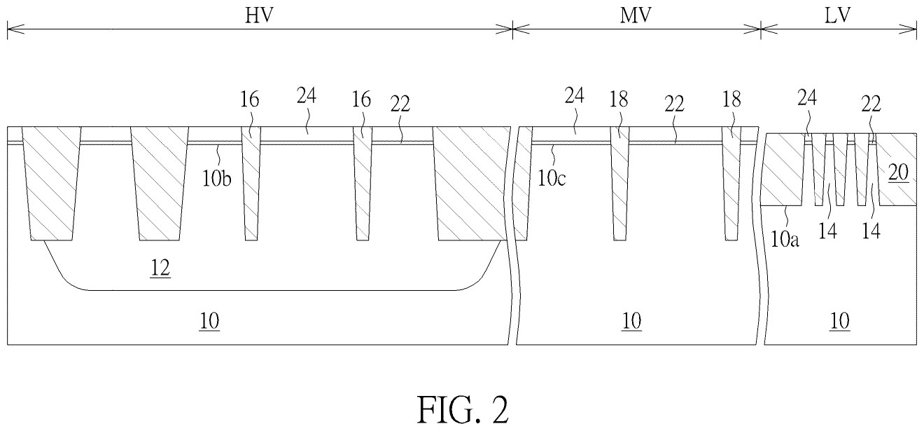

As shown in FIG. 2, a high voltage well 12 is formed in the substrate 10 of the high voltage region HV. The high voltage well 12 may be formed by using an ion implantation process. In this embodiment, the high voltage well 12 may be a P-type well. However, in different embodiments, the high voltage well 12 may be an N-type well. Thereafter, at least one fin structure 14 is formed in the low voltage region LV. Then, the first deep trench isolations 16 and the second deep trench isolations 18 are formed simultaneously by the same process. The first deep trench isolations 16 are located in the high voltage region HV, and the second deep trench isolations 18 are located in the middle voltage region MV.

Now, the substrate 10 of the low voltage region LV has a first surface 10a, and the fin structure 14 protrudes from the first surface 10a. In this embodiment, four fin structures 14 are taken as an example. Two shallow trench isolations (STIs) 20 are respectively disposed at two sides of the fin structure 14 and the entire fin structure 14 is embedded in the STIs 20. Two first deep trench isolations 16 are embedded in the substrate 10 of the high voltage region HV. Two second deep trench isolations 18 are embedded in the substrate 10 of the middle voltage region MV. The substrate 10 in the high voltage region HV has a second surface 10b, and the substrate 10 in the middle voltage region MV has a third surface 10c. In this stage, the second surface 10b and the third surface 10c are aligned with each other. Furthermore, the first surface 10a is lower than the second surface 10b. The first deep trench isolations 16 in the high voltage region HV and the second deep trench isolations 18 in the middle voltage region MV are formed from the same horizontal plane of the substrate 10, therefore, the fin structures 14 which protruding from the STIs 20 will have uniformed length even on different chips. The length of the protruding fin structures 14 may not change along with the variation of the aspect ratio of the first deep trench isolations 16 and the second deep trench isolations 18.

Please refer to FIG. 2. A pad silicon oxide 22 and a pad silicon nitride 24 are formed to cover the second surface 10b, the third surface 10c and the top surface of the fin structure 14. Part of the first deep trench isolations 16 and part of the second deep trench isolations 18 are embedded in the pad silicon nitride 24 and the pad silicon oxide 22. The first deep trench isolations 16, the second deep trench isolations 18 and the STIs 20 include silicon oxide.

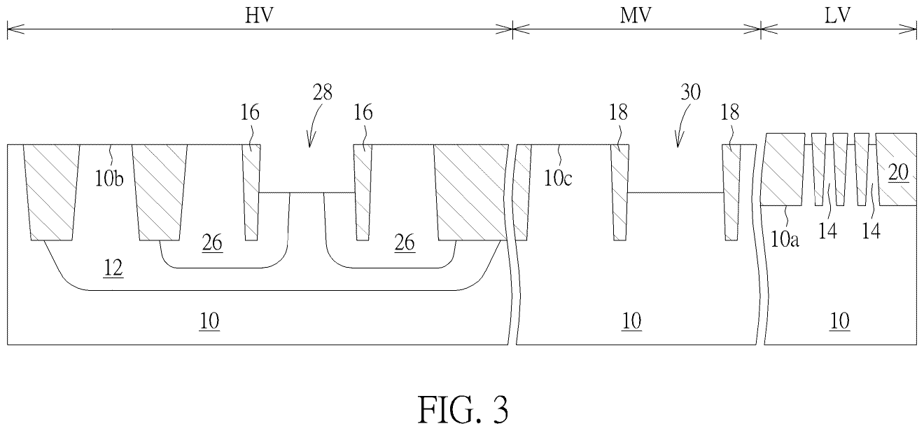

As shown in FIG. 3, the pad silicon nitride 24 and the pad silicon oxide 22 are completely removed. Later, a drift region 26 is formed in the substrate 10 of the high voltage region HV. In this embodiment, the drift region 26 can be an N-type drift region. In other embodiments, the drift region 26 can also be a P-type drift region. Next, a mask (not shown) is formed to cover the low voltage region LV, part of the middle voltage region MV, and part of the high voltage region HV, so that the substrate 10 between the two first deep trench isolations 16 and between the two second deep trench isolations 18 is exposed. Subsequently, the second surface 10b between the first deep trench isolations 16 is etched while etching the third surface 10c between the second deep trench isolations 18 to form a first trench 28 and a second trench 30. The first trench 28 is between the first deep trench isolations 16, and the second trench 30 is between the second deep trench isolations 18. Because the first trench 28 and the second trench 30 are formed by the same process at same time, a depth of the first trench 28 and a depth of the second trench 30 are the same. Next, the mask is removed.

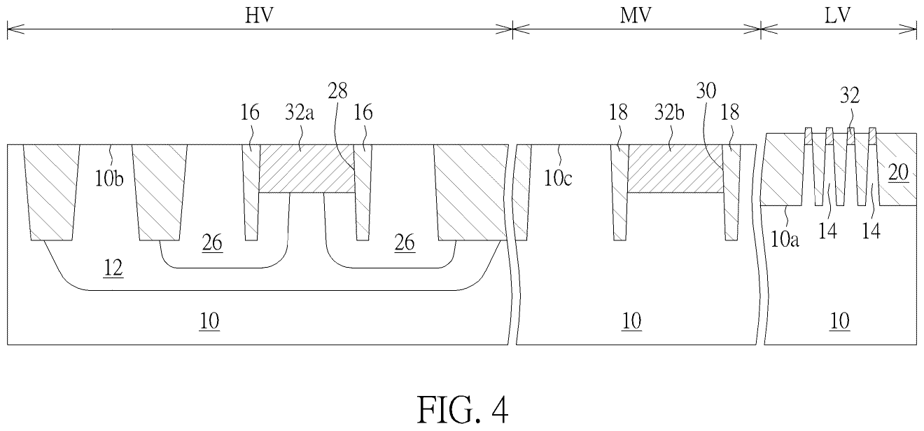

As shown in FIG. 4, an oxidation process such as a rapid thermal oxidation process (RTO) is performed to form a silicon oxide layer filling the first trench 28, the second trench 30 and on the top surface of the fin structure 14, and to cover the surface of the substrate 10. Subsequently, the silicon oxide layer 32 is etched back to remove the silicon oxide layer 32 on the second surface 10b and the third surface 10c of the substrate 10. At this time, the silicon oxide layer 32 remaining in the first trench 28 is defined as a first silicon oxide layer 32a, and the silicon oxide layer 32 remaining in the second trench 30 is defined as a second silicon oxide layer 32b. The first silicon oxide layer 32a, the second silicon oxide layer 32b, the second surface 10b and the third surface 10c are aligned with each other.

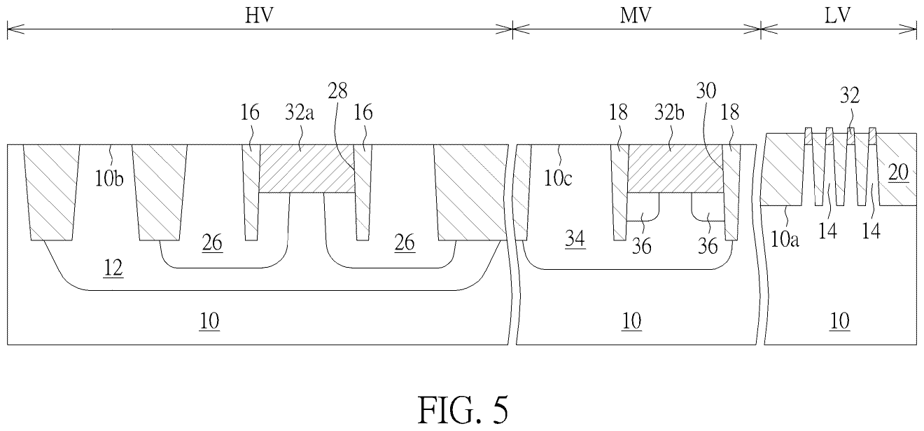

As shown in FIG. 5, a middle voltage well 34 is formed and embedded in the substrate 10 of the middle voltage region MV. The middle voltage well 34 is preferably a P-type well. In different embodiments, the middle voltage well 34 may also be an N-type well. Later, two lightly doping regions 36 are formed in the substrate 10 between the two second deep trench isolations 18. In details, two lightly doping regions 36 are located below the second silicon oxide layer 32b and between the two deep trench isolations 18. The lightly doping regions 36 are preferably N-type. In different embodiments, the lightly doping regions 36 may also be P-type.

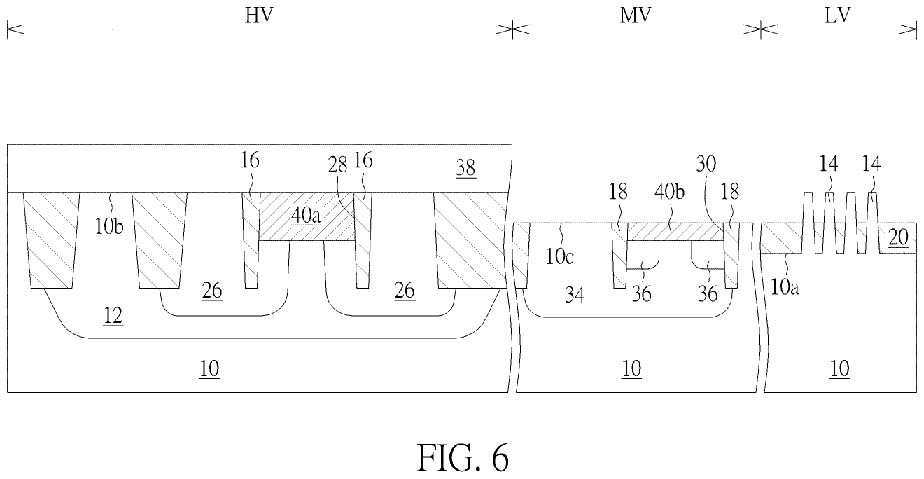

Please refer to FIG. 5 and FIG. 6. A mask 38 is formed to cover the high voltage region HV and expose the middle voltage region MV and the low voltage region LV. Next, a low voltage well (not shown) is formed in the fin structure 14. Then, part of the second silicon oxide layer 32b, part of the second deep trench isolations 18, part of the third surface 10c, part of the STIs 20 and the silicon oxide layer 32 on the fin structure 14 are simultaneously removed to make a thickness of the second silicon oxide layer 32b and thicknesses of the STIs 20 become thinner. Furthermore, after thinning, the top surface of the second silicon oxide layer 32b is lower than the top surface of the first silicon oxide layer 32a. At this time, the thinned second silicon oxide layer 32b serves as the second gate dielectric layer 40b. The first silicon oxide layer 32a in the first trench 28 serves as the first gate dielectric layer 40a. Moreover, the removing of the second silicon oxide layer 32b and the STIs 20 may be performed by an etching back process. After the etching back process, the top surface of the second gate dielectric layer 40b will be aligned with the top surfaces of the STIs 20. The top surface of the second gate dielectric layer 40b is aligned with the top surfaces of the second deep trench isolations 18 and the third surface 10c. Furthermore, the bottom of the first gate dielectric layer 40a and the bottom of the second gate dielectric layer 40b are higher than the bottoms of the STIs 20. In addition, after the etching back, part of the fin structure 14 protrudes from the top surfaces of the STIs 20. The top surface of the fin structure 14, the first gate dielectric layer 40a, the top surfaces of the first deep trench isolations 16 and the second surface 10b are aligned with each other.

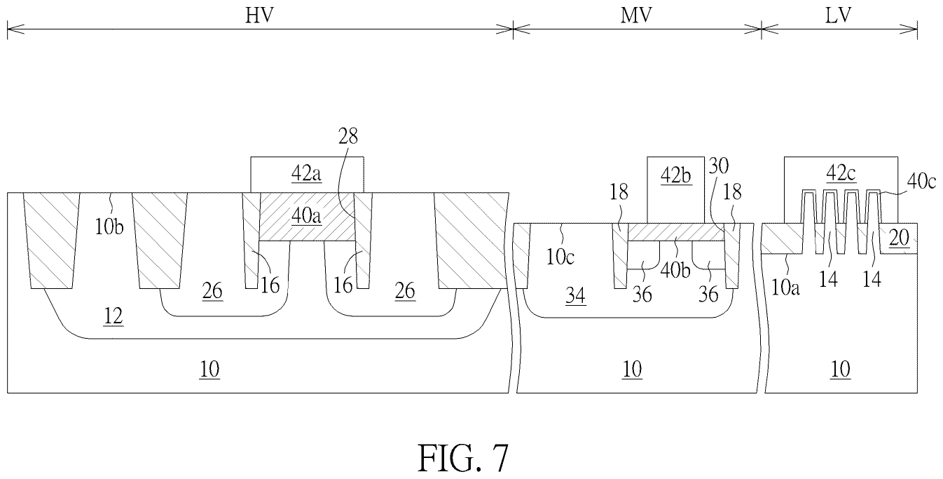

As shown in FIG. 7, the mask 38 is removed. Next, a third gate dielectric layer 40c is formed to cover the protruding fin structure 14. The third gate dielectric layer 40c is preferably silicon oxide. Thereafter, a conductive layer (not shown) is formed blankly to cover the substrate 10. The conductive layer can be polysilicon, metal or other conductive materials. Later, the conductive layer is patterned to form a first gate structure 42a, a second gate structure 42b and a third gate structure 42c. The first gate structure 42a is disposed on the first gate dielectric layer 40a. The second gate structure 42b is disposed on the second gate dielectric layer 40b. The third gate structure 42c covers and crosses each fin structure 14 and is disposed on the third gate dielectric layer 40c. The top surface of the first gate structure 42a, the top surface of the second gate structure 42b and the top surface of the third gate structure 42c are aligned. Next, an epitaxial layer (not shown) is formed on the fin structure 14 to serve as a source and a drain of a low voltage transistor.

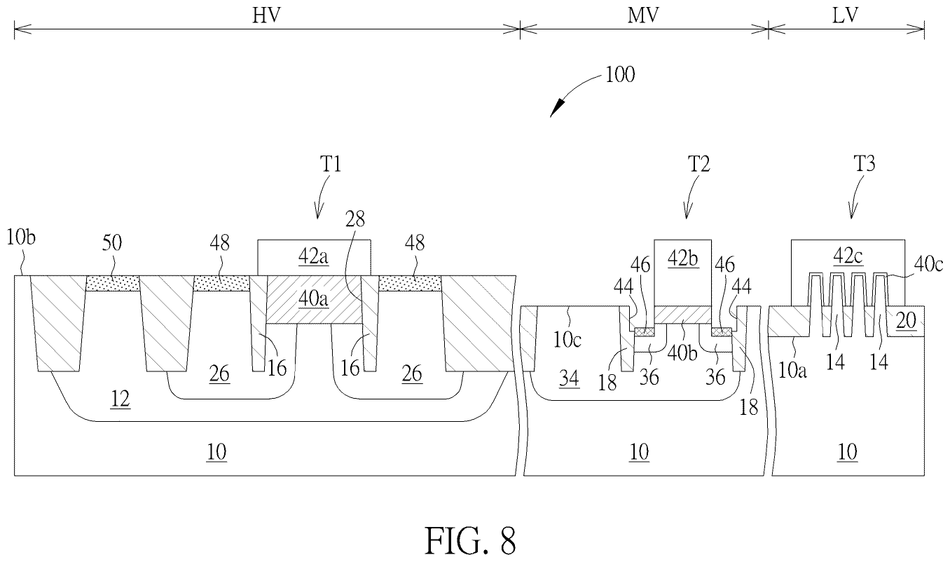

As shown in FIG. 8, the second gate dielectric layer 40b and the substrate 10 at two sides of the second gate structure 42b are etched to form two recesses 44. The substrate 10 is exposed from the bottom of the recesses 44. Subsequently, two silicides 46 are formed respectively in the two recesses 44 to serve as a source and a drain of a middle voltage transistor. Silicides 46 include nickel silicon compounds. Then, two doping regions 48 are formed in the substrate 10 at two sides of the first gate dielectric layer 40a. Doping regions 48 serve as a source and a drain of a high voltage transistor. The doping region 48 is preferably N-type. In different embodiments, the doped region 48 may also be P-type. In addition, a doping region 50 is formed in the high voltage well 12. The doping region 50 is preferably P-type, and in different embodiments, the doping region 50 may also be N-type. Now, a structure 100 with a high voltage transistor, a middle voltage transistor and a low voltage transistor of the present invention is completed.

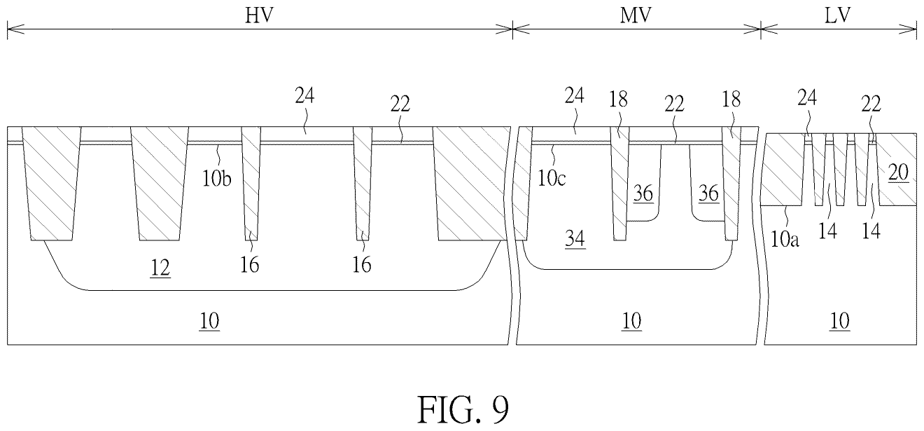

FIG. 9 depict a fabricating method of a structure with a high voltage transistor, a middle voltage transistor and a low voltage transistor according to a second preferred embodiment of the present invention, wherein elements which are substantially the same as those in the first preferred embodiment are denoted by the same reference numerals; an accompanying explanation is therefore omitted.

FIG. 9 depicts a fabricating stage in continuous of FIG. 2. As shown in FIG. 9, after forming the first deep trench isolations 16 and the second deep trench isolations 18, the middle voltage well 34 and the lightly doping regions 36 are formed. In the second preferred embodiment, the middle voltage well 34 and the lightly doping regions 36 are formed before forming the first trench 28 and the second trench 30 shown in FIG. 3. In the first preferred embodiment, the middle voltage well 34 and the lightly doping regions 36 are formed after forming the first trench 28 and the second trench 30 and before removing part of the second silicon oxide layer 32b shown in FIG. 5.

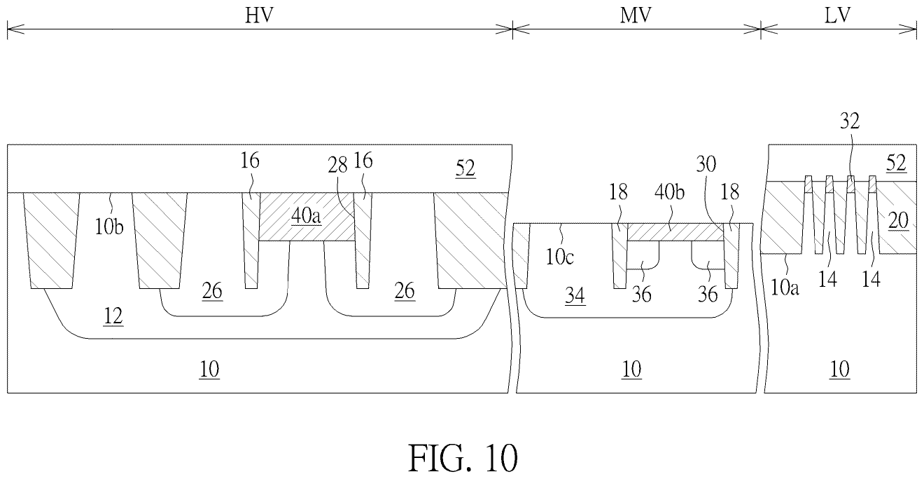

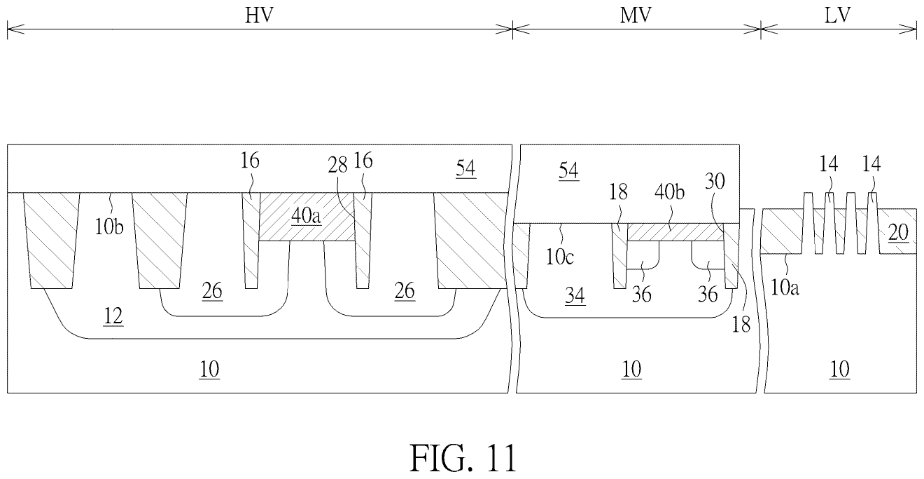

FIG. 10 to FIG. 11 depict a fabricating method of a structure with a high voltage transistor, a middle voltage transistor and a low voltage transistor according to a third preferred embodiment of the present invention, wherein elements which are substantially the same as those in the first preferred embodiment are denoted by the same reference numerals; an accompanying explanation is therefore omitted.

FIG. 10 depicts a fabricating stage in continuous of FIG. 5. As shown in FIG. 5 and FIG. 10, after the second silicon oxide layer 32b is formed, a mask 52 is formed to cover the high voltage region HV and the low voltage region LV. Later, part of the second silicon oxide layer 32b is removed to form the second gate dielectric layer 40b. As shown in FIG. 11, the mask 52 is removed. Next, a mask 54 is formed to cover the high voltage region HV and the middle voltage region MV. After that, part of the STIs 20 and the silicon oxide layer 32 on fin structures 14 are removed. In the third preferred embodiment, the second silicon oxide layer 32b and the STIs 20 are removed performed separately. Therefore, the top surface of the second gate dielectric layer 40b and the top surface of the STIs 20 are not aligned in the in the final structure. In the first preferred embodiment, the second silicon oxide layer 32b and the STIs 20 are removed in the same step. Therefore, the top surface of the second gate dielectric layer 40b and the top surfaces of the STIs 20 are aligned.

As shown in FIG. 8, a structure 100 with a high voltage transistor, a middle voltage transistor and a low voltage transistor includes a substrate 10. The substrate includes a high voltage region HV, a middle voltage region MV and a low voltage region LV. A high voltage transistor T1 is disposed in the high voltage region HV, a middle voltage transistor T2 is disposed in the middle voltage region MV, and a low voltage transistor T3 is disposed in the low voltage region LV. The substrate 10 in the high voltage region HV has a second surface 10b, and the substrate 10 in the middle voltage region MV has a third surface 10c. The substrate 10 of the low voltage region LV has a first surface 10a. The second surface 10b is higher than the third surface 10c, and the first surface 10a is lower than the third surface 10c.

The high voltage transistor T1 includes a first gate dielectric layer 40a embedded in the substrate 10, and a first gate structure 42a disposed on the first gate dielectric layer 40a. The top surface of the first gate dielectric layer 40a is aligned with the second surface 40b. Moreover, two first deep trench isolations 16 are embedded in the substrate 10 in the high voltage region HV. The first deep trench isolations 16 are respectively disposed at two sides of the first gate dielectric layer 40a and connected to the first gate dielectric layer 40a. The two doping regions 48 of the high voltage transistor T1 are respectively disposed in the substrate 10 at two sides of the first gate dielectric layer 40a. Each doping region 48 is adjacent to one of the first deep trench isolations 16.

The middle voltage transistor T2 includes a second gate dielectric layer 40b embedded in the substrate 10. The top surface of the second gate dielectric layer 40b is aligned with the third surface 10c. A second gate structure 42b is disposed on the second gate dielectric layer 40b. The thickness of the second gate structure 42b is greater than the thickness of the first gate structure 42a. Two second deep trench isolations 18 are embedded in the substrate 10 of the middle voltage region MV. The second deep trench isolations 18 are respectively located at two sides of the second gate dielectric layer 40b. Two lightly doping regions 36 are in the substrate 10 between the second deep trench isolations 18, and the lightly doping regions 36 are at two sides of the second gate dielectric layer 40b. Two silicides 46 are respectively disposed in the substrate 10 at two sides of the second gate dielectric layer 40b, wherein each of the two silicides 46 is disposed between one of the two second deep trench isolations 18 and the second gate dielectric layer 40b.

The low voltage transistor T3 includes at least one fin structure 14 protruding from a first surface 10a of the substrate 10. A third gate structure 42c covers and crosses the fin structure 14. An STI covers the first surface 10a of the substrate 10 in the low voltage region LV and is disposed at one side of the fin structure 14. The fin structure 14 protrudes from the STI 20. The top surface of the STI 20 is aligned with the top surface of the second gate dielectric layer 40b. Moreover, a thickness of the third gate structure 42c is the same as a thickness of the second gate structure 42b.

The fabricating process of the present invention starts from the top surface of the substrate in the middle voltage region and the high voltage region are aligned. In this way, the fin structures which protruding from the STIs will have uniformed length on the same substrate. Even on different substrates of the same batch that the protruding part of the fin structures can have substantially the same length. The length of the protruding fin structures may not change along with the variation of the aspect ratio of the first deep trench isolations and the second deep trench isolations. Therefore, more stable semiconductor performance can be reached.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A structure with a high voltage transistor, a middle voltage transistor and a low voltage transistor, comprising:
a substrate, wherein the substrate comprises a high voltage region, a middle voltage region and a low voltage region;
a high voltage transistor disposed in the high voltage region, wherein the high voltage transistor comprises a first gate dielectric layer embedded in the substrate and a first gate structure disposed on the first gate dielectric layer;
a middle voltage transistor disposed in the middle voltage region, wherein the middle voltage transistor comprises a second gate dielectric layer embedded in the substrate, and a second gate structure disposed on the second gate dielectric layer;
a low voltage transistor disposed in the low voltage region, wherein the low voltage transistor comprises a fin structure protruding from a first surface of the substrate, and a third gate structure covering and crossing the fin structure; and
a shallow trench insulation (STI) covering the first surface of the substrate in the low voltage region and disposed at one side of the fin structure, wherein the fin structure protrudes from the STI, and a top surface of the STI is aligned with a top surface of the second gate dielectric layer.

2. The structure with a high voltage transistor, a middle voltage transistor and a low voltage transistor of claim 1, wherein the high voltage region of the substrate has a second surface, the middle voltage region of the substrate has a third surface, the second surface is higher than the third surface, and the first surface is lower than the third surface.

3. The structure with a high voltage transistor, a middle voltage transistor and a low voltage transistor of claim 2, wherein a top surface of the first gate dielectric layer is aligned with the second surface, and the top surface of the second gate dielectric layer is aligned with the third surface.

4. The structure with a high voltage transistor, a middle voltage transistor and a low voltage transistor of claim 1, further comprising:
two first deep trench isolations embedded in the high voltage region of the substrate, wherein the two first deep trench isolations are respectively disposed at two sides of the first gate dielectric layer and connected to the first gate dielectric layer; and
two second deep trench isolations embedded in the middle voltage region of the substrate, wherein the two second deep trench isolations are respectively disposed at two sides of the second gate dielectric layer.

5. The structure with a high voltage transistor, a middle voltage transistor and a low voltage transistor of claim 4, further comprising:
two doping regions respectively disposed in the substrate at two sides of the first gate dielectric layer; and
two silicides respectively disposed in the substrate at two sides of the second gate dielectric layer, wherein each of the two silicides is disposed between one of the two second deep trench isolations and the second gate dielectric layer.

6. The structure with a high voltage transistor, a middle voltage transistor and a low voltage transistor of claim 1, wherein a thickness of the third gate structure and a thickness of the second gate structure are the same.

7. A structure with a high voltage transistor, a middle voltage transistor and a low voltage transistor, comprising:
a substrate, wherein the substrate comprises a high voltage region, a middle voltage region and a low voltage region;
a high voltage transistor disposed in the high voltage region, wherein the high voltage transistor comprises a first gate dielectric layer embedded in the substrate and a first gate structure disposed on the first gate dielectric layer; and
a middle voltage transistor disposed in the middle voltage region, wherein the middle voltage transistor comprises a second gate dielectric layer embedded in the substrate, and a second gate structure disposed on the second gate dielectric layer, wherein a thickness of the second gate structure is greater than a thickness of the first gate structure.

8. The structure with a high voltage transistor, a middle voltage transistor and a low voltage transistor of claim 7, further comprising:
a low voltage transistor disposed in the low voltage region, wherein the low voltage transistor comprises a fin structure protruding from a first surface of the substrate, and a third gate structure covering and crossing the fin structure; and
a shallow trench insulation (STI) covering the first surface of the substrate in the low voltage region and disposed at one side of the fin structure.

9. The structure with a high voltage transistor, a middle voltage transistor and a low voltage transistor of claim 8, wherein the high voltage region of the substrate has a second surface, the middle voltage region of the substrate has a third surface, the second surface is higher than the third surface, and the first surface is lower than the third surface.

10. The structure with a high voltage transistor, a middle voltage transistor and a low voltage transistor of claim 9, wherein a top surface of the first gate dielectric layer is aligned with the second surface, and a top surface of the second gate dielectric layer is aligned with the third surface.

11. The structure with a high voltage transistor, a middle voltage transistor and a low voltage transistor of claim 7, further comprising:
two first deep trench isolations embedded in the high voltage region of the substrate, wherein the two first deep trench isolations are respectively disposed at two sides of the first gate dielectric layer and connected to the first gate dielectric layer; and
two second deep trench isolations embedded in the middle voltage region of the substrate, wherein the two second deep trench isolations are respectively disposed at two sides of the second gate dielectric layer.

12. The structure with a high voltage transistor, a middle voltage transistor and a low voltage transistor of claim 11, further comprising:
two doping regions respectively disposed in the substrate at two sides of the first gate dielectric layer; and
two silicides respectively disposed in the substrate at two sides of the second gate dielectric layer, wherein each of the two silicides is disposed between one of the two second deep trench isolations and the second gate dielectric layer.

13. A fabricating method of a structure with a high voltage transistor, a middle voltage transistor and a low voltage transistor, comprising:
providing a substrate, wherein the substrate comprises a high voltage region, a middle voltage region and a low voltage region, and wherein the low voltage region of the substrate has a first surface, at least one fin structure protrudes from the first surface, a shallow trench insulation (STI) is disposed at one side of the fin structure, two first deep trench isolations are embedded in the substrate of the high voltage region, two second deep trench isolations are embedded in the substrate of the middle voltage region, the high voltage region of the substrate has a second surface, and the middle voltage region of the substrate has a third surface, the second surface and the third surface are aligned, and the first surface is lower than the second surface;
etching the first surface and the second surface to form a first trench and a second trench, wherein the first trench is disposed between the two first deep trench isolations and the second trench is disposed between the two second deep trench isolations;
forming a first silicon oxide layer and a second silicon oxide layer respectively filling the first trench and the second trench, wherein the first silicon oxide layer and the second silicon oxide layer are aligned;
removing part of the second silicon oxide layer to make a top surface of the second silicon oxide layer lower than a top surface of the first silicon oxide layer;
removing part of the STI to expose part of the fin structure; and
after removing part of the second silicon oxide layer, forming a first gate structure, a second gate structure and a third gate structure to respectively cover the first silicon oxide layer, the second silicon oxide layer and the fin structure.

14. The fabricating method of a structure with a high voltage transistor, a middle voltage transistor and a low voltage transistor of claim 13, wherein a depth of the first trench and a depth of the second trench are the same.

15. The fabricating method of a structure with a high voltage transistor, a middle voltage transistor and a low voltage transistor of claim 13, wherein the part of the second silicon oxide layer and the part of the STI are both removed by the same etching back process.

16. The fabricating method of a structure with a high voltage transistor, a middle voltage transistor and a low voltage transistor of claim 15, wherein after the etching back process, the top surface of the second silicon oxide layer is aligned with a top surface of the STI.

17. The fabricating method of a structure with a high voltage transistor, a middle voltage transistor and a low voltage transistor of claim 13, wherein a thickness of the second gate structure is greater than a thickness of the first gate structure.

18. The fabricating method of a structure with a high voltage transistor, a middle voltage transistor and a low voltage transistor of claim 13, further comprising before forming the first trench and the second trench, forming two lightly doping regions in the substrate between the two second deep trench isolations.

19. The fabricating method of a structure with a high voltage transistor, a middle voltage transistor and a low voltage transistor of claim 13, further comprising before removing the part of the second silicon oxide layer, forming two lightly doping regions in the substrate between the two second deep trench isolations.
